(19) United States
(12) Patent Application Publication
(10) Pub. No.: US 2024/0330540 A1
(43) Pub. Date: Oct. 3, 2024

(54) Method of Pre-warning and Identifying Fault of Relay Protection of Intelligent Substation

(71) Applicant: INNER MONGOLIA POWER (GROUP) CO., LTD INNER MONGOLIA POWER RESEARCH INSTITUTE, Huhhot (CN)

(72) Inventors: Jiangping WANG, Huhhot (CN); Zaixin YANG, Huhhot (CN); Minfu A, Huhhot (CN); Jun TAO, Huhhot (CN); Yunmin WANG, Huhhot (CN); Rucheng ZHOU, Huhhot (CN); Yedong TAOPU, Huhhot (CN); Yannan QU, Huhhot (CN); Jiangyi GE, Huhhot (CN); Ke MA, Huhhot (CN); Yuzhu WU, Huhhot (CN)

(73) Assignee: INNER MONGOLIA POWER (GROUP) CO., LTD INNER MONGOLIA POWER RESEARCH INSTITUTE, Huhhot (CN)

(21) Appl. No.: 18/596,690

(22) Filed: Mar. 6, 2024

(30) Foreign Application Priority Data
Mar. 29, 2023 (CN) 202310328246.0

(51) Int. Cl. G06F 30/20

(52) U.S. Cl. CPC G06F 30/20

(57) ABSTRACT

A method of pre-warning and identifying a fault of relay protection of an intelligent substation is provided, which is specifically carried out according to following steps. Step 1: performing fault diagnosis on hardware input signals of relay protection equipment; step 2: performing software fault diagnosis on a relay protection device; step 3: developing a MATLAB-based anti-false pre-warning platform for the relay protection of the intelligent substation by combining step 1 and step 2; and step 4: based on the MATLAB-based anti-false pre-warning platform for the relay protection of the intelligent substation, according to fault recording sampling information of the substation, accurately identifying a fault area, pre-judging a possible action situation of protection, and giving pre-warning information.

### TECHNICAL FIELD

The present disclosure belongs to the technical field of fault identification, and particularly relates to a method of pre-warning and identifying a fault of relay protection of an intelligent substation.

### BACKGROUND ART

The relay protection is first defense for safe and stable operation of electric power systems. A false or failed action of relay protection will cause device damage and extension of accident range. Pre-warning and identifying a fault of relay protection can solve a problem that a single relay protection device has insufficient capacity of distinguishing secondary circuit and interlocking fault. If, according to sampling information about fault recording of a substation, a fault area can be accurately identified, a possible action situation can be pre-judged, and certain pre-warning information and the like can be given, fault pre-warning information can be provided for relay protection workers, so as to help the relay protection workers to take corresponding safety measures. Thus, it is necessary to pre-warn and identify a type of the fault of the relay protection.

At present, the invisible secondary circuit of the intelligent substation causes it more difficult to check problems of relay protection equipment. It is necessary to pre-warn and analyze software and hardware faults and problems of the relay protection equipment of the intelligent substation, so as to timely find the problems, and thereby pertinently take response strategies.

### SUMMARY

An object of the present disclosure is to provide a method of pre-warning and identifying a fault of relay protection of an intelligent substation, which solves the problem of how to determine possible fault situations of a relay protection device by a fault diagnosis method.

Technical solutions adopted in the present disclosure are as follows.

A method of pre-warning and identifying a fault of relay protection of an intelligent substation, which is specifically carried out according to following steps:
step 1: performing fault diagnosis on hardware input signals of relay protection equipment;
step 2: performing software fault diagnosis on a relay protection device;
step 3: developing a MATLAB-based anti-false pre-warning platform for the relay protection of the intelligent substation by combining step 1 and step 2; and
step 4: based on the MATLAB-based anti-false pre-warning platform for the relay protection of the intelligent substation, according to fault recording sampling information of the substation, accurately identifying a fault area, pre-judging a possible action situation of protection, and giving pre-warning information.

The present disclosure further has the following characteristics.

Step 1 specifically is:
step 1.1, classifying and dividing non-fault signals in current signals using information fed in for protection, calculating Euclidean distances between various utility points for the non-fault signals by an abnormal data detection method, and detecting input data;
step 1.2, firstly classifying collected signals, wherein a short-circuit current in case of fault is a fault signal, and others are the non-fault signals;
step 1.3, establishing classification indexes for the fault signals and other non-fault signals, wherein by calculating signal classification indexes Q and q, two classes, i.e., load current signal and abnormal current caused by a hardware fault in a data collection channel, can be divided, so as to identify the hardware fault in the data collection channel;
step 1.4, classifying hardware faults by abnormal data detection, wherein a method for the abnormal data detection may be implemented by calculating distances between various utility points;
step 1.5, preventing misjudgement caused by interference through two following formula (3) and formula (4), wherein if a judgement condition is satisfied, it may be taken as a condition for starting the abnormal data detection, and the Euclidean distances are taken as a criterion for the abnormal data detection:

$${d}_{ki} = \frac{1}{N} {( {\sum }_{p = 1}^{N} {\vert {i}_{k + p} - {i}_{k + p - N} \vert}^{2} )}^{\frac{1}{2}} > ε ; \qquad ( 3 )$$

$${d}_{k u} = \frac{1}{N} {( {\sum }_{p 1}^{N} {\vert {u}_{k + p} - {u}_{k + p - N} \vert}^{2} )}^{\frac{1}{2}} > ε ; \qquad ( 4 )$$

in the formulas, N represents the number of sampling points in one cycle, if a value of a threshold ε is large, possible error or hardware fault data in measurement can be distinguished from two situations of TV and TA breakage (disconnection) and measurement circuit fault disconnection;
step 1.6, according to calculation results of steps 2.3 and 2.4, judging a fault cause if distances of current and voltage are greater than a standard value; and
step 1.7, completing the fault diagnosis of the hardware input signals of the relay protection equipment.

In step 1.2, input signals are divided into seven classes: load current under a given load condition; current under a varying load; abnormal current caused by hardware fault in a data collection channel; short-circuit current under fault condition; TA breakage current; TV breakage voltage signal; and measuring circuit breakage voltage and current signal.

Step 1.4 specifically is: calling each record of the collected voltage and current as an original point, selecting fields that need to be compared therefrom, and calling these fields as utility points, so as to calculate absolutes distances between various utility points of the current and voltage, and calculating formulas (1) and (2) as follows:

$${d}_{i} = \vert {i}_{k} - {i}_{k - N} \vert > ε ; \qquad ( 1 )$$

$${d}_{u} = \vert {u}_{k} - {u}_{k - N} \vert > ε . \qquad ( 2 )$$

In the formulas, iₖ represents a current sampling value; and uₖ represents a voltage sampling value; and if the above two formulas satisfy a judgment condition, it is considered as abnormal data.

Step 2 specifically is:
step 2.1, after a system failure, starting to calculate branch and switch correlation matrixes, and selecting a direction information matrix thus protected according to a calculation result;
step 2.2, according to a selected node number, determining direction information about two sides of the determined node with node number, thereby obtaining a result of power direction sum of a correlation domain;
step 2.3, judging a fault area using information about the power direction sum of the correlation domain, wherein the correlation domain with the lowest power direction sum is the fault area;
step 2.4, according to a selection result of the fault area and an action situation of protection, analyzing to obtain a result of whether the protection is a correct action, and determining a protection situation of false action or failed action;
step 2.5, completing a flow of software fault diagnosis of the relay protection device.

Step 4 specifically is:
step 3.1, in a situation of normal operation of the system, establishing a substation model according to input operation parameters of the substation, giving an operation state of the system in a normal state, and evaluating whether a device in an input channel of the relay protection device has abnormality in a normal operation state according to input current and voltage waveforms of the relay protection device, and giving a pre-judgment result for a possible action situation of the protection; and
step 3.2, in a situation where the system has a fault, regardless of an in-area fault or an out-of-area fault, according to current and voltage waveforms actually collected by a fault recorder when the fault occurs, selecting a fault area using a fault area identification method of the information about the power direction sum, and according to the selected fault area, for the protection that needs to be pre-judged, firstly, judging whether the fault is an in-area or out-of-area fault, secondly, judging a section where the fault occurs, further, pre-judging a possible action situation of the protection, and giving pre-warning information.

The beneficial effects of the present disclosure are as follows. The method of pre-warning and identifying a fault of relay protection of an intelligent substation in the present disclosure is different from preceding methods that cannot conveniently and quickly diagnose fault situations due to factors such as influence of network structure and no universality for fault diagnosis of relay equipment of the intelligent substation. Regardless of location of a fault point and presence or absence of transition resistance, this method can effectively identify the fault area, prejudge a possible action situation of the protection, and give certain pre-warning information. This method is not affected by the mesh structure, and can accurately identify the fault area and correctly give certain pre-warning information no matter in a condition of transformer breakage or transformer saturation.

### BRIEF DESCRIPTION OF DRAWINGS

FIG. 1 shows a flow of fault diagnosis of hardware input signals in a method of pre-warning and identifying a fault of relay protection of an intelligent substation in the present disclosure;

FIG. 2 shows a flow of software fault diagnosis in the method of pre-warning and identifying a fault of relay protection of an intelligent substation in the present disclosure;

FIG. 3 is a schematic diagram of a MATLAB anti-false pre-warning platform for the relay protection of the intelligent substation in the method of pre-warning and identifying a fault of relay protection of an intelligent substation in the present disclosure;

FIG. 4 shows a pre-judgment flow of the method of pre-warning and identifying a fault of relay protection of an intelligent substation in the present disclosure in a normal operation situation; and

FIG. 5 shows pre-judgment of the method of pre-warning and identifying a fault of relay protection of an intelligent substation in the present disclosure in a fault operation state.

### DETAILED DESCRIPTION OF EMBODIMENTS

A method of pre-warning and identifying a fault of relay protection of an intelligent substation in the present disclosure is described in detail below in conjunction with the drawings and specific embodiments.

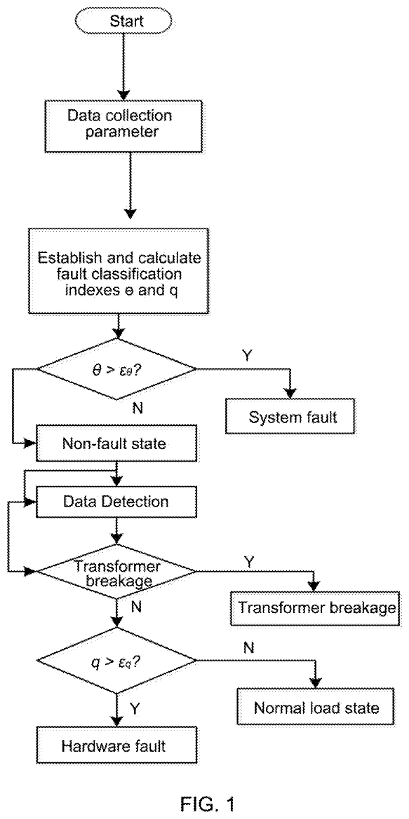

As shown in FIG. 1, it shows a flow of fault diagnosis of hardware input signals of relay protection equipment in the method of pre-warning and identifying a fault of relay protection of an intelligent substation in the present disclosure.

It is specifically implemented according to the following steps.

Step 1.1, performing fault diagnosis on hardware input signals of the relay protection equipment.

Step 1.2, classifying and dividing non-fault signals in current signals using information such as voltage and current fed in for protection, calculating Euclidean distances between various utility points for the non-fault signals by an abnormal data detection method, and detecting input data.

Step 1.3, firstly classifying collected signals, and dividing input signals into seven classes, that is, load current under a given load condition; current under a varying load; abnormal current caused by hardware fault in a data collection channel; short-circuit current in case under fault condition; TA breakage current; TV breakage voltage signal; and measuring circuit breakage voltage and current signal. In the above, the short-circuit current under fault condition is a fault signal, and the others are non-fault signals.

Step 1.4, establishing classification indexes for the fault signals and other non-fault signals. By calculating signal classification indexes Q and q, two classes, i.e., load current signal and abnormal current caused by a hardware fault in the data collection channel, can be divided, so as to identify the hardware fault in the data collection channel.

Step 1.5, classifying hardware faults by abnormal data detection. The method for abnormal data detection may be implemented by calculating distances between various utility points. Each record of voltage and current collected is called as an original point, fields that need to be compared are selected therefrom, and these fields are called as utility points. Thus, absolutes distances between various effect points of the current and voltage are calculated. Following formulas are calculated:

$${d}_{i} = \vert {i}_{k} - {i}_{k - N} \vert > ε \qquad ( 1 )$$

$${d}_{u} = \vert {u}_{k} - {u}_{k - N} \vert > ε \qquad ( 2 )$$

In the formulas, iₖ represents a current sampling value; and uₖ represents a voltage sampling value. If the above two formulas satisfy a judgment condition, it is considered as abnormal data.

Step 1.6, in order to prevent misjudgement caused by interference, if the following two formulas satisfy a judgement condition, they may be used as a condition for starting abnormal data detection, and the Euclidean distances are taken as a criterion for the abnormal data detection:

$${d}_{k i} = \frac{1}{N} {( {\sum }_{p = 1}^{N} {\vert {i}_{k + p} - {i}_{k + p - N} \vert}^{2} )}^{\frac{1}{2}} > ε ; \qquad ( 3 )$$

$${d}_{k u} = \frac{1}{N} {( {\sum }_{p = 1}^{N} {\vert {u}_{k + p} - {u}_{k + p - N} \vert}^{2} )}^{\frac{1}{2}} > ε . \qquad ( 4 )$$

In the formulas, N represents the number of sampling points in one cycle. If a value of a threshold ε is large, possible error or hardware fault data in the measurement can be distinguished from the two situations of TV and TA breakage and measurement circuit fault disconnection.

Step 1.7, according to calculation results of steps 2.3 and 2.4, judging a fault cause if distances of current and voltage are obviously large. If the current is large and the voltage is normal, a current transformer may be disconnected; if the voltage is large and the current is normal, a voltage transformer may be short-circuited; and if the current is large and the voltage is large, the measurement circuit may have a fault and be disconnected.

Step 1.8: completing the fault diagnosis of the hardware input signals of the relay protection equipment by combining the above implementation processes.

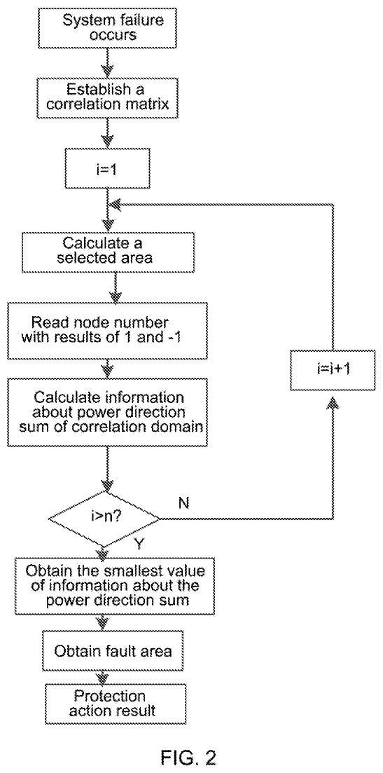

As shown in FIG. 2, it shows a flow of software fault diagnosis of a relay protection device in the method of pre-warning and identifying a fault of relay protection of an intelligent substation in the present disclosure.

Step 2.1, after a system failure, starting to calculate branch and switch correlation matrixes, and selecting a direction information matrix thus protected according to a calculation result.

Step 2.2, according to a selected node number, calculating direction information about two sides of the determined node with the node number, thereby obtaining a result of power direction sum of a correlation domain.

Step 2.3, judging a fault area using information about the power direction sum of the correlation domain, wherein the correlation domain with the lowest power direction sum is the fault area.

Step 2.4, according to a selection result of the above fault area and an action situation of protection, analyzing to obtain a result of whether it is a correct action for the protection, and determining a protection situation of false action or failed action.

Step 2.5, completing the flow of software fault diagnosis of the relay protection device by combining the above implementation processes.

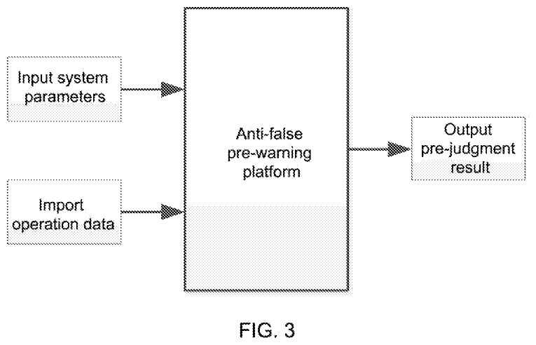

Step 3, establishing a a MATLAB-based platform for pre-warning and identifying a fault of relay protection of the intelligent substation by combining step 1 and step 2. The platform may implement two pre-warning functions, one is pre-judging in a normal operation condition, i.e., predicting a possible action result of protection in a normal operation state, and verifying correctness of the result through the fault; and the other is pre-judging in case of fault, and pre-judging a possible action situation of protection according to an actual fault that occurs in the system. FIG. 3 is a schematic diagram of an anti-false pre-warning platform for the relay protection.

Step 3 is specifically implemented according to the following steps.

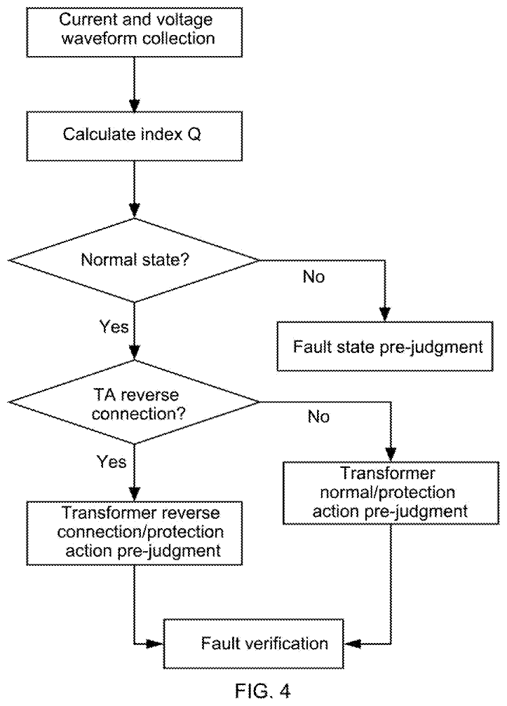

Step 3.1, in a situation of normal operation of the system, establishing a substation model according to input substation operation parameters, giving an operation state of the system in the normal state, and evaluating whether a device in an input channel of the relay protection device has abnormality, such as reverse connection of a secondary side of the transformer, in the normal operation state according to the input current and voltage waveforms of the relay protection device, and giving a pre-judgment result for a possible action situation of this protection. FIG. 4 shows a pre-judgment flow in the normal operation situation.

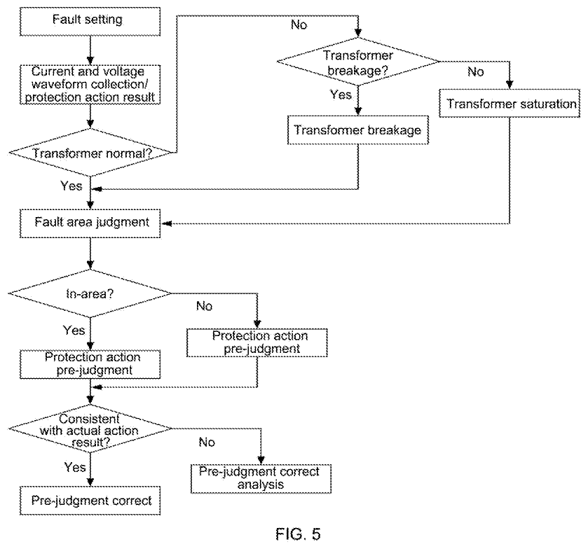

Step 3.2, in a situation where the system has a fault, regardless of an in-area fault or an out-of-area fault, according to current and voltage waveforms actually collected by a fault recorder when the fault occurs, selecting a fault area using a fault area identification method of the information about the power direction sum, and according to the selected fault area, for the protection that needs to be pre-judged, firstly, judging whether it is an in-area or out-of-area fault, secondly, judging a section where the fault occurs, further, pre-judging a possible action situation of the protection, and giving certain pre-warning information. FIG. 5 shows a pre-judgment flow in a fault operation state.

The method of pre-warning and identifying a fault of relay protection of an intelligent substation in the present disclosure can determine possible existence of a fault in the relay protection device by the fault diagnosis method, and further can give certain pre-warning information, thus improving a security factor, and having a relatively good practical significance.

What is claimed is:

1. A method of pre-warning and identifying a fault of relay protection of an intelligent substation, comprising steps of:
step 1: performing fault diagnosis on hardware input signals of relay protection equipment;
step 2: performing software fault diagnosis on a relay protection device;
step 3: developing a MATLAB-based anti-false pre-warning platform for the relay protection of the intelligent substation by combining step 1 and step 2; and
step 4: identifying accurately a fault area, based on the MATLAB-based anti-false pre-warning platform for the relay protection of the intelligent substation, according to fault recording sampling information of the substation, pre-judging a possible action situation of protection, and giving pre-warning information.

2. The method of pre-warning and identifying a fault of relay protection of an intelligent substation according to claim 1, wherein step 1 comprises:
step 1.1, classifying and dividing non-fault signals in current signals using information fed in for protection, calculating, for the non-fault signals, Euclidean distances between various utility points by an abnormal data detection method, and detecting input data;
step 1.2, classifying collected signals firstly, wherein a short-circuit current in case of fault is a fault signal, and others are the non-fault signals;
step 1.3, establishing classification indexes for the fault signals and other non-fault signals, wherein by calculating signal classification indexes Q and q, two classes, i.e., load current signal and abnormal current caused by a hardware fault in a data collection channel, can be divided, so as to identify the hardware fault in the data collection channel;
step 1.4, classifying hardware faults by abnormal data detection, wherein a method for the abnormal data detection may be implemented by calculating distances between various utility points;
step 1.5, preventing misjudgement caused by interference through two following formula (3) and formula (4), wherein if a judgement condition is satisfied, it may be taken as a condition for starting the abnormal data detection, and the Euclidean distances are taken as a criterion for the abnormal data detection:
$${d}_{ki} = \frac{1}{N} {( {\sum }_{p = 1}^{N} {\vert {i}_{k + p} - {i}_{k + p - N} \vert}^{2} )}^{\frac{1}{2}} > ε ; \qquad ( 3 )$$
$$and$$
$${d}_{k u} = \frac{1}{N} {( {\sum }_{p 1}^{N} \vert {u}_{k + p} - {u}_{k + p - N} {\vert}^{2} )}^{\frac{1}{2}} > ε ; \qquad ( 4 )$$
in the formulas, N represents number of sampling points in one cycle, wherein if a value of a threshold ε is large, possible error or hardware fault data in measurement can be distinguished from two situations of TV and TA breakage and measurement circuit fault disconnection;
step 1.6, judging, according to calculation results of steps 2.3 and 2.4, a fault cause if distances of current and voltage are greater than a standard value; and
step 1.7, completing the fault diagnosis of the hardware input signals of the relay protection equipment.

3. The method of pre-warning and identifying a fault of relay protection of an intelligent substation according to claim 2, wherein in step 1.2, input signals are divided into seven classes: load current under a given load condition; current under a varying load; abnormal current caused by hardware fault in a data collection channel; short-circuit current under fault condition; TA breakage current; TV breakage voltage signal; and measuring circuit breakage voltage and current signal.

4. The method of pre-warning and identifying a fault of relay protection of an intelligent substation according to claim 2, wherein step 1.4 comprises: calling each record of the collected voltage and current as an original point, selecting fields that need to be compared therefrom, and calling these fields as utility points, so as to calculate absolutes distances between various effect points of the current and voltage, and calculating formulas (1) and (2) as follows:
$${d}_{i} = \vert {i}_{k} - {i}_{k - N} \vert > ε ; \qquad ( 1 )$$
$$and$$
$${d}_{u} = \vert {u}_{k} - {u}_{k - N} \vert > ε ; \qquad ( 2 )$$
in the formulas, iₖ represents a current sampling value; and uₖ represents a voltage sampling value; and if the above two formulas satisfy a judgment condition, it is considered as abnormal data.

5. The method of pre-warning and identifying a fault of relay protection of an intelligent substation according to claim 1, wherein step comprises:
step 2.1, starting to calculate branch and switch correlation matrixes after a system failure, and selecting a direction information matrix thus protected according to a calculation result;
step 2.2, calculating, according to a selected node number, direction information about two sides of the determined node with the node number, thereby obtaining a result of power direction sum of a correlation domain;
step 2.3, judging a fault area using information about the power direction sum of the correlation domain, wherein the correlation domain with the lowest power direction sum is the fault area;
step 2.4, analyzing, according to a selection result of the fault area and an action situation of protection, to obtain a result of whether it is a correct action for the protection, and determining a protection situation of false action or failed action;
step 2.5, completing a flow of software fault diagnosis of the relay protection device.

6. The method of pre-warning and identifying a fault of relay protection of an intelligent substation according to claim 1, wherein step 4 comprises:
step 3.1, establishing, in a situation of normal operation of the system, a substation model according to input operation parameters of the substation, giving an operation state of the system in a normal state, and evaluating, according to input current and voltage waveforms of the relay protection device, whether a device in an input channel of the relay protection device has abnormality in a normal operation state, and giving a pre-judgment result for a possible action situation of the protection; and
step 3.2, selecting a fault area, in a situation where the system has a fault, regardless of an in-area fault or an out-of-area fault, according to current and voltage waveforms actually collected by a fault recorder when the fault occurs, using a fault area identification method of the information about the power direction sum, judging firstly, according to the selected fault area, for the protection that needs to be pre-judged, whether it is an in-area or out-of-area fault, judging secondly, a section where the fault occurs, further pre-judging a possible action situation of the protection, and giving a pre-warning information.
